(19) United States
(12) Patent Application Publication
(10) Pub. No.: US 2022/0376074 A1
(43) Pub. Date: Nov. 24, 2022

(54) NITRIDE-BASED SEMICONDUCTOR DEVICE AND METHOD FOR MANUFACTURING THE SAME

(71) Applicant: INNOSCIENCE (SUZHOU) TECHNOLOGY CO., LTD., Suzhou City (CN)

(72) Inventors: Ronghui HAO, Suzhou City (CN); Qingyuan HE, Suzhou City (CN); Fu CHEN, Suzhou City (CN); King Yuen WONG, Suzhou City (CN)

(21) Appl. No.: 17/417,120

(22) PCT Filed: May 3, 2021
(86) PCT No.: PCT/CN2021/091802

§ 371 Date: Jun. 22, 2021

(51) Int. Cl. H01L 29/47; H01L 29/20; H01L 29/205; H01L 29/778; H01L 29/40; H01L 29/66

(52) U.S. Cl. CPC H01L 29/475; H01L 29/2003; H01L 29/205; H01L 29/7786; H01L 29/401; H01L 29/66462

(57) ABSTRACT

A nitride-based semiconductor device includes a first and second nitride-based semiconductor layers, a doped III-V semiconductor layer, a gate electrode, a first and second source/drain (S/D) electrodes. The doped III-V semiconductor layer is disposed over the second nitride-based semiconductor layer and has first and second current-leakage barrier portions which extends downward from atop surface of the doped III-V semiconductor layer. The gate electrode is disposed above the doped III-V semiconductor layer, in which the gate electrode has a pair of opposite edges between the first and second current-leakage barrier portions. One of the edges of the gate electrode coincides with the first current-leakage barrier portion. The first current-leakage barrier portion is located between the first S/D electrode and the gate electrode. The second current-leakage barrier portion is located between the second S/D electrode and the gate electrode.

### FIELD OF THE DISCLOSURE

The present disclosure generally relates to a nitride-based semiconductor device. More specifically, the present disclosure relates to a nitride-based semiconductor device having current-leakage barrier portions for improving electrical characteristics of the semiconductor device.

### BACKGROUND OF THE DISCLOSURE

In recent years, intense research on high-electron-mobility transistors (HEMTs) has been prevalent, particularly for high power switching and high frequency applications. III-nitride-based HEMTs utilize a heterojunction interface between two materials with different bandgaps to form a quantum well-like structure, which accommodates a two-dimensional electron gas (2DEG) region, satisfying demands of high power/frequency devices. In addition to HEMTs, examples of devices having heterostructures further include heterojunction bipolar transistors (HBT), heterojunction field effect transistor (HFET), and modulation-doped FETs (MODFET).

### SUMMARY OF THE DISCLOSURE

In accordance with one aspect of the present disclosure, a nitride-based semiconductor device is provided. A nitride-based semiconductor device includes a first nitride-based semiconductor layer, a second nitride-based semiconductor layer, a doped III-V semiconductor layer, a gate electrode, a first source/drain (S/D) electrode and a second S/D electrode. The second nitride-based semiconductor layer is disposed on the first nitride-based semiconductor layer and has a bandgap greater than a bandgap of the first nitride-based semiconductor layer. The doped III-V semiconductor layer is disposed over the second nitride-based semiconductor layer and has first and second current-leakage barrier portions which extend downward from a top surface of the doped III-V semiconductor layer. The gate electrode is disposed above the doped III-V semiconductor layer, in which the gate electrode has a pair of opposite edges between the first and second current-leakage barrier portions. One of the edges of the gate electrode coincides with the first current-leakage barrier portion. The first source/drain (S/D) electrode is disposed above the second nitride-based semiconductor layer, in which the first current-leakage barrier portion is located between the first S/D electrode and the gate electrode. The second S/D electrode is disposed above the second nitride-based semiconductor layer, in which the second current-leakage barrier portion is located between the second S/D electrode and the gate electrode.

In accordance with one aspect of the present disclosure, a method for manufacturing a semiconductor device is provided. The method includes steps as follows. A first nitride-based semiconductor layer is formed on a substrate. A second nitride-based semiconductor layer is formed on the first nitride-based semiconductor layer. A blanket doped III-V semiconductor layer is formed on the second nitride-based semiconductor layer. A gate electrode is formed on the blanket doped III-V semiconductor layer. A surface treatment is performed on the blanket doped III-V semiconductor layer using the gate electrode as a mask during the surface treatment, such that at least one portion of the blanket doped III-V semiconductor layer becomes a current-leakage barrier portion. The blanket doped III-V semiconductor layer is patterned to form a doped III-V semiconductor layer wider than the gate electrode. Two or more source/drain (S/D) electrodes are formed on the second nitride-based semiconductor layer and at opposite sides of the gate electrode.

In accordance with one aspect of the present disclosure, a nitride-based semiconductor device is provided. A III-nitride-based semiconductor device includes a first nitride-based semiconductor layer, a second nitride-based semiconductor layer, a doped III-V semiconductor layer, and two or more source/drain (S/D) electrodes. The second nitride-based semiconductor layer is disposed on the first nitride-based semiconductor layer and has a bandgap greater than a bandgap of the first nitride-based semiconductor layer. The gate electrode is disposed above the second nitride-based semiconductor layer. The doped III-V semiconductor layer is disposed between the second nitride-based semiconductor layer and the gate electrode and having a pair of current-leakage barrier portions to confine the rest portion of the doped III-V semiconductor layer from an interface between the gate electrode and the doped III-V semiconductor layer, in which the rest portion of the doped III-V semiconductor layer has a width substantially the same as that of the interface between the gate electrode and the doped III-V semiconductor layer. Two or more source/drain (S/D) electrodes are disposed above the second nitride-based semiconductor layer, in which the remaining portion of the doped III-V semiconductor layer is located between the S/D electrodes.

By applying the above configuration, the doped III-V semiconductor layer has current-leakage barrier portions extending from the top surface thereof, such that the probability of generating current leakage is decreased, the reliability of the gate electrode is enhanced, improving the performance of the nitride-based semiconductor device.

### BRIEF DESCRIPTION OF THE DRAWINGS

Aspects of the present disclosure are readily understood from the following detailed description when read with the accompanying figures. It should be noted that various features may not be drawn to scale. That is, the dimensions of the various features may be arbitrarily increased or reduced for clarity of discussion. Embodiments of the present disclosure are described in more detail hereinafter with reference to the drawings, in which:

FIG. 1A is a top view of a nitride-based semiconductor device according to some embodiments of the present disclosure;

FIG. 1B is a vertical cross-sectional view across a line A-A′ of the semiconductor device in FIG. 1A;

FIG. 2 is a vertical cross-sectional view of a semiconductor device according to a comparative embodiment;

FIG. 3A, FIG. 3B, FIG. 3C, FIG. 3D, FIG. 3E, and FIG. 3F show different stages of a method for manufacturing the nitride-based semiconductor device according to some embodiments of the present disclosure;

FIG. 4 is a vertical cross-sectional view of a nitride-based semiconductor device according to some embodiments of the present disclosure;

FIG. 5 is a vertical cross-sectional view of a nitride-based semiconductor device according to some embodiments of the present disclosure;

FIG. 6 is a vertical cross-sectional view of a nitride-based semiconductor device according to some embodiments of the present disclosure;

FIG. 7A is a vertical cross-sectional view of a nitride-based semiconductor device according to some embodiments of the present disclosure;

FIG. 7B shows a stage of a method for manufacturing the nitride-based semiconductor device in FIG. 7A according to some embodiments of the present disclosure;

FIG. 8A is a vertical cross-sectional view of a nitride-based semiconductor device according to some embodiments of the present disclosure;

FIG. 8B shows a stage of a method for manufacturing the nitride-based semiconductor device in FIG. 8A according to some embodiments of the present disclosure; and

FIG. 9 is a vertical cross-sectional view of a nitride-based semiconductor device according to some embodiments of the present disclosure.

FIG. 10 is a vertical cross-sectional view of a nitride-based semiconductor device according to some embodiments of the present disclosure.

### DETAILED DESCRIPTION

Common reference numerals are used throughout the drawings and the detailed description to indicate the same or similar components. Embodiments of the present disclosure will be readily understood from the following detailed description taken in conjunction with the accompanying drawings.

Spatial descriptions, such as “on,” “above,” “below,” “up,” “left,” “right,” “down,” “top,” “bottom,” “vertical,” “horizontal,” “side,” “higher,” “lower,” “upper,” “over,” “under,” and so forth, are specified with respect to a certain component or group of components, or a certain plane of a component or group of components, for the orientation of the component(s) as shown in the associated figure. It should be understood that the spatial descriptions used herein are for purposes of illustration only, and that practical implementations of the structures described herein can be spatially arranged in any orientation or manner, provided that the merits of embodiments of this disclosure are not deviated from by such arrangement.

Further, it is noted that the actual shapes of the various structures depicted as approximately rectangular may, in actual device, be curved, have rounded edges, have somewhat uneven thicknesses, etc. due to device fabrication conditions. The straight lines and right angles are used solely for convenience of representation of layers and features.

In the following description, semiconductor devices/dies/packages, methods for manufacturing the same, and the likes are set forth as preferred examples. It will be apparent to those skilled in the art that modifications, including additions and/or substitutions may be made without departing from the scope and spirit of the present disclosure. Specific details may be omitted so as not to obscure the present disclosure; however, the disclosure is written to enable one skilled in the art to practice the teachings herein without undue experimentation.

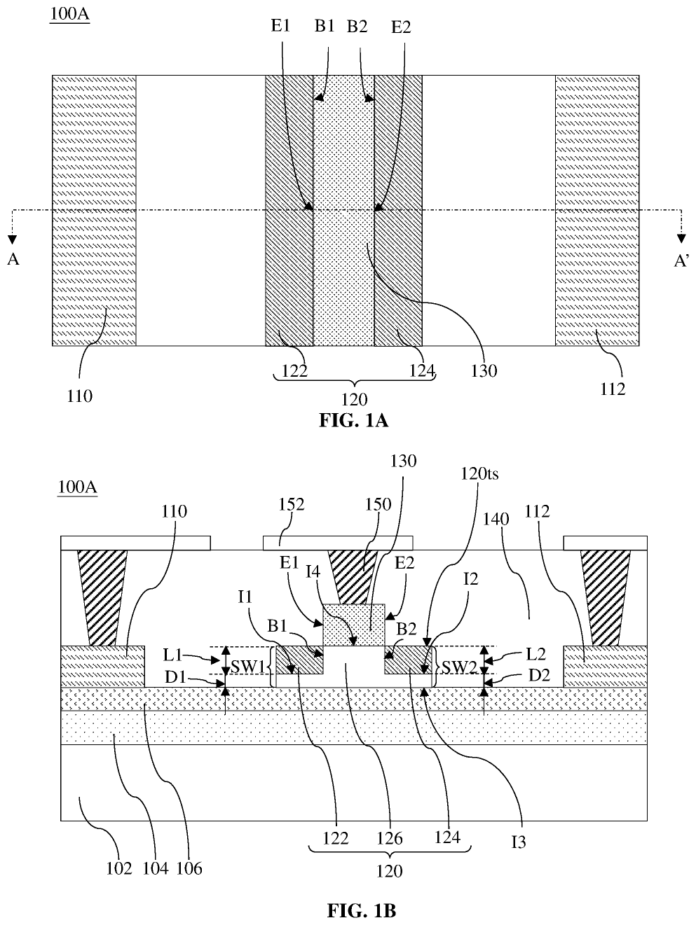

FIG. 1A is a top view of a nitride-based semiconductor device according to some embodiments of the present disclosure. FIG. 1B is a vertical cross-sectional view across a line A-A′ of the semiconductor device in FIG. 1A. For clarity, some elements are omitted in some figures.

Referring to FIGS. 1A and 1, the semiconductor device 100A includes a substrate 102, nitride-based semiconductor layers 104 and 106, S/D electrodes 110 and 112, a doped III-V semiconductor layer 120, a gate electrode 130, a passivation layer 140, a plurality of contact vias 150 (which can be referred to as conductive vias), and a patterned conductive layer 152.

The substrate 102 may be a semiconductor substrate. The exemplary materials of the substrate 102 can include, for example but are not limited to, Si, SiGe, SiC, gallium arsenide, p-doped Si, n-doped Si, sapphire, semiconductor on insulator, such as silicon on insulator (SOI), or other suitable substrate materials. In some embodiments, the substrate 102 can include, for example, but is not limited to, group III elements, group IV elements, group V elements, or combinations thereof (e.g., III-V compounds). In other embodiments, the substrate 102 can include, for example but is not limited to, one or more other features, such as a doped region, a buried layer, an epitaxial (epi) layer, or combinations thereof.

The nitride-based semiconductor layer 104 is disposed over the substrate 102. The nitride-based semiconductor layer 106 is disposed on the nitride-based semiconductor layer 104. The exemplary materials of the nitride-based semiconductor layer 104 can include, for example but are not limited to, nitrides or group III-V compounds, such as GaN, AlN, InN, InₓAl_{y}Ga_{(1-x-y)}N where x+y≤1, Al_{y}Ga_{(1-y)}N where y≤1. The exemplary materials of the nitride-based semiconductor layer 106 can include, for example but are not limited to, nitrides or group III-V compounds, such as GaN, AlN, InN, InₓAl_{y}Ga_{(1-x-y)}N where x+y≤1, Al_{y}Ga_{(1-y)}N where y≤1.

The exemplary materials of the nitride-based semiconductor layers 104 and 106 are selected such that the nitride-based semiconductor layer 106 has a bandgap (i.e., forbidden band width) greater than a bandgap of the nitride-based semiconductor layer 104, which causes electron affinities thereof different from each other and forms a heterojunction therebetween. For example, when the nitride-based semiconductor layer 104 is an undoped GaN layer having a bandgap of approximately 3.4 eV, the nitride-based semiconductor layer 106 can be selected as an AlGaN layer having bandgap of approximately 4.0 eV. As such, the nitride-based semiconductor layers 104 and 106 can serve as a channel layer and a barrier layer, respectively. A triangular well potential is generated at a bonded interface between the channel and barrier layers, so that electrons accumulate in the triangular well, thereby generating a two-dimensional electron gas (2DEG) region adjacent to the heterojunction. Accordingly, the semiconductor device 100A is available to include at least one GaN-based high-electron-mobility transistor (HEMT).

In some embodiments, the semiconductor device 100A may further include a buffer layer, a nucleation layer, or a combination thereof (not illustrated). The buffer layer can be disposed between the substrate 102 and the nitride-based semiconductor layer 104. The buffer layer can be configured to reduce lattice and thermal mismatches between the substrate 102 and the nitride-based semiconductor layer 104, thereby curing defects due to the mismatches/difference. The buffer layer may include a III-V compound. The III-V compound can include, for example but are not limited to, aluminum, gallium, indium, nitrogen, or combinations thereof. Accordingly, the exemplary materials of the buffer layer can further include, for example but are not limited to, GaN, AlN, AlGaN, InAlGaN, or combinations thereof. The nucleation layer may be formed between the substrate 102 and the buffer layer. The nucleation layer can be configured to provide a transition to accommodate a mismatch/difference between the substrate 102 and a III-nitride layer of the buffer layer. The exemplary material of the nucleation layer can include, for example but is not limited to AlN or any of its alloys.

The S/D electrodes 110 and 112 are disposed on the nitride-based semiconductor layer 106. The “S/D” electrode means each of the S/D electrodes 110 and 112 can serve as a source electrode or a drain electrode, depending on the device design. In some embodiments, the S/D electrodes 110 and 112 can include, for example but are not limited to, metals, alloys, doped semiconductor materials (such as doped crystalline silicon), compounds such as silicides and nitrides, other conductor materials, or combinations thereof. The exemplary materials of the S/D electrodes 110 and 112 can include, for example but are not limited to, Ti, AlSi, TiN, or combinations thereof. The S/D electrodes 110 and 112 may be a single layer, or plural layers of the same or different composition. In some embodiments, the S/D electrodes 110 and 112 form ohmic contact with the nitride-based semiconductor layer 106. The ohmic contact can be achieved by applying Ti, Al, or other suitable materials to the S/D electrodes 110 and 112. In some embodiments, each of the S/D electrodes 110 and 112 is formed by at least one conformal layer and a conductive filling. The conformal layer can wrap the conductive filling. The exemplary materials of the conformal layer, for example but are not limited to, Ti, Ta, TiN, Al, Au, AlSi, Ni, Pt, or combinations thereof. The exemplary materials of the conductive filling can include, for example but are not limited to, AlSi, AlCu, or combinations thereof.

The doped III-V semiconductor layer 120 is disposed on the nitride-based semiconductor layer 106. The gate electrode 130 is disposed on the doped III-V semiconductor layer 120. The combination of the doped III-V semiconductor layer 120 and the gate electrode 130 is located between the S/D electrodes 110 and 112. That is, the S/D electrodes 110 and 112 can be located at two opposite sides of the gate electrode 130. In some embodiments, other configurations may be used, particularly when plural source, drain, or gate electrodes are employed in the device. In the exemplary illustration of FIG. 1, the S/D electrodes 110 and 112 are symmetrical about the gate electrode 130. In other embodiments, the S/D electrodes 110 and 112 are asymmetrical about the gate electrode 130. For example, the S/D electrode 110 can be closer to the gate electrode 130 than the S/D electrode 112.

In the exemplary illustration of FIG. 1B, the semiconductor device 100A is an enhancement mode device, which is in a normally-off state when the gate electrode 130 is at approximately zero bias. Specifically, the doped III-V semiconductor layer 120 may create at least one p-n junction with the nitride-based semiconductor layer 106 to deplete the 2DEG region, such that at least one zone of the 2DEG region corresponding to a position below the corresponding the gate electrode 130 has different characteristics (e.g., different electron concentrations) than the rest of the 2DEG region and thus is blocked. Due to such mechanism, the semiconductor device 100A has a normally-off characteristic. In other words, when no voltage is applied to the gate electrode 130 or a voltage applied to the gate electrode 130 is less than a threshold voltage (i.e., a minimum voltage required to form an inversion layer below the gate electrode 130), the zone of the 2DEG region below the gate electrode 130 is kept blocked, and thus no current flows therethrough.

The doped III-V semiconductor layer 120 can be a p-type doped III-V semiconductor layer. The exemplary materials of the doped III-V semiconductor layer 120 can include, for example but are not limited to, p-doped group III-V nitride semiconductor materials, such as p-type GaN, p-type AlGaN, p-type InN, p-type AlInN, p-type InGaN, p-type AlInGaN, or combinations thereof. In some embodiments, the p-doped materials are achieved by using a p-type impurity, such as Be, Mg, Zn, Cd, and Mg. In some embodiments, the nitride-based semiconductor layer 104 includes undoped GaN and the nitride-based semiconductor layer 106 includes AlGaN, and the doped III-V semiconductor layer 120 is a p-type GaN layer which can bend the underlying band structure upwards and to deplete the corresponding zone of the 2DEG region, so as to place the semiconductor device 100A into an off-state condition.

The doped III-V semiconductor layer 120 has a top surface 120ts facing away from the nitride-based semiconductor layer 106 and facing the gate electrode 130. The doped III-V semiconductor layer 120 has current-leakage barrier portions 122 and 124. The current-leakage barrier portion 122 is located between the S/D electrode 110 and the gate electrode 130. The current-leakage barrier portion 124 is located between the S/D electrode 112 and the gate electrode 130. The remaining portion 126 of doped III-V semiconductor layer 120, which is located between the current-leakage barrier portions 122 and 124, can be defined by the current-leakage barrier portions 122 and 124. Herein, the definition regarding the remaining portion 126 of doped III-V semiconductor layer 120 includes that the remaining portion 126 has a profile/boundary defined by the current-leakage barrier portions 122 and 124.

The current-leakage barrier portions 122 and 124 are respectively located at two sides of the gate electrode 130. The current-leakage barrier portions 122 and 124 and the remaining portion 126 can include the same material but different concentrations. For example, the current-leakage barrier portions 122 and 124 and the rest portion 126 can include gallium (Ga), in which concentrations of Ga in the current-leakage barrier portions 122 and 124 is different than that of the remaining portion 126.

In some embodiments, the current-leakage barrier portions 122 and 124 are formed by oxidizing a doped GaN layer and thus can include gallium oxide such as Ga₂O₃, GaON, GaMgON, or combinations thereof. Accordingly, the concentration of Ga in the remaining portion 126 is higher than that in the current-leakage barrier portions 122 and 124. Similarly, the oxygen concentration of the current-leakage barrier portions 122 and 124 would be higher than that of the remaining portion 126 of the doped III-V semiconductor layer 120.

In some embodiments, the current-leakage barrier portions 122 and 124 are formed by doping certain foreign atoms and thus can include high resistive elements, such as fluorine (F), nitrogen (N), oxygen (O), argon (Ar), silicon (Si) or combinations thereof. Accordingly, the concentration of Ga in the rest portion 126 is higher than that in the current-leakage barrier portions 122 and 124. In some embodiments, the doped concentration is in a range from about 1*10⁸ cm⁻³ to about 1*10²² cm⁻³.

Briefly, the current-leakage barrier portions 122 and 124 can be formed to have the resistivity higher than that of rest portion 126 of the doped III-V semiconductor layer 120 by introducing certain foreign atoms to the doped III-V semiconductor layer 120. Accordingly, the current-leakage barrier portions 122 and 124 can be referred to as high resistivity portions and the remaining portion 126 of the doped III-V semiconductor layer 120 can be referred to as low resistivity portions in the doped III-V semiconductor layer 120.

The exemplary materials of the gate electrode 130 may include metals or metal compounds. The gate electrode 130 may be formed as a single layer, or plural layers of the same or different compositions. The exemplary materials of the metals or metal compounds can include, for example but are not limited to, W, Au, Pd, Ti, Ta, Co, Ni, Pt, Mo, TiN, TaN, metal alloys or compounds thereof, or other metallic compounds.

During the formation of the current-leakage barrier portions 122 and 124, the gate electrode 130 can serve as a mask, so the current-leakage barrier portions 122 and 124 can have boundaries depending on the gate electrode 130. For example, the gate electrode 130 is disposed above the doped III-V semiconductor layer 120 and have two opposite edges between the current-leakage barrier portions 122 and 124. The gate electrode 130 is in contact with the remaining portion 126 of the doped III-V semiconductor layer 120.

For convenience of description the relationship among the gate electrode, the current-leakage barrier portions, and other elements layer, some terminologies are defined as follows:
I1 represents an interface between the current-leakage barrier portion 122 and the remaining portion 126 of the doped III-V semiconductor layer 120 which is closest to the nitride-based semiconductor layer 106;
I2 represents an interface between the current-leakage barrier portion 124 and the remaining portion 126 of the doped III-V semiconductor layer 120 which is closest to the nitride-based semiconductor layer 106;
I3 represents an interface between the remaining portion 126 of the doped III-V semiconductor layer 120 and the nitride-based semiconductor layer 106;
I4 represents an interface between the remaining portion 126 of the doped III-V semiconductor layer 120 and the gate electrode 130;
B1 represents an inner boundary of the current-leakage barrier portion 122 which is located inside the doped III-V semiconductor layer 120, and the inner boundary B1 also can be referred to as a side interface between the current-leakage barrier portion 122 and the remaining portion 126 of the doped III-V semiconductor layer 120;
B2 represents an inner boundary of the current-leakage barrier portion 124 which is located inside the doped III-V semiconductor layer 120, and the inner boundary B2 also can be referred to as a side interface between the current-leakage barrier portion 124 and the remaining portion 126 of the doped III-V semiconductor layer 120;
D1 represents a distance between the two interfaces I1 and I3;
D2 represents a distance between the two interfaces I2 and I3;
E1 and E2 represent the opposite edges of the gate electrode 130, wherein the edge E1 is adjacent to the current-leakage barrier portion 122 and the edge E2 is adjacent to the current-leakage barrier portion 124; and
SW1 and SW2 represent the opposite sidewalls of the doped III-V semiconductor layer 120, in which the sidewall SW1 is adjacent to the current-leakage barrier portion 122 and the sidewall SW2 is adjacent to the current-leakage barrier portion 124.

The edge E1 can coincide with the inner boundary B1 of the current-leakage barrier portion 122 at the top surface 120ts of the doped III-V semiconductor layer 120. The edge E2 can coincide with the inner boundary B2 of the current-leakage barrier portion 124 at the top surface 120ts of the doped III-V semiconductor layer 120. In the exemplary illustration of FIG. 1B, the current-leakage barrier portions 122 and 124 are free from vertically overlapping with the gate electrode 130. The profiles of the current-leakage barrier portions 122 and 124 can be quadrilateral profiles, for example, rectangular profiles. In some embodiments, the profiles of the current-leakage barrier portions 122 and 124 can be square profiles, and the disclosure is not limited thereto. Each of the current-leakage barrier portions 122 and 124 extends downward from the top surface 120ts. The current-leakage barrier portions 122 can span partially the sidewall SW1 and thus is spaced apart from the nitride-based semiconductor layer 106. Similarly, the current-leakage barrier portions 124 can span partially the sidewall SW2 and thus is spaced apart from the nitride-based semiconductor layer 106. The current-leakage barrier portions 122 can span with an extending length L1 from the top surface 120ts to the interface I1. The current-leakage barrier portions 124 can span with an extending length L2 from the top surface 120ts to the interface I2. In some embodiments, the extending length L1 is substantially equal to the extending length L2. Accordingly, the distance D1 and the distance D2 can be non-zero and substantially equal to each other. Moreover, in some embodiments, the extending length L1 can be designed to be different from the extending length L2 based on different electrical characteristic requirements. Namely, the distance D1 can be different from the distance D2. For example, the distance D1 can be greater or less than the distance D2.

Furthermore, the remaining portion 126 of the doped III-V semiconductor layer can have a top with a width the same as a width of the interface I4. The reason is that the gate electrode 130 can serve as a mask during the formation of the current-leakage barrier portions 122 and 124, which can simplify the manufacturing process.

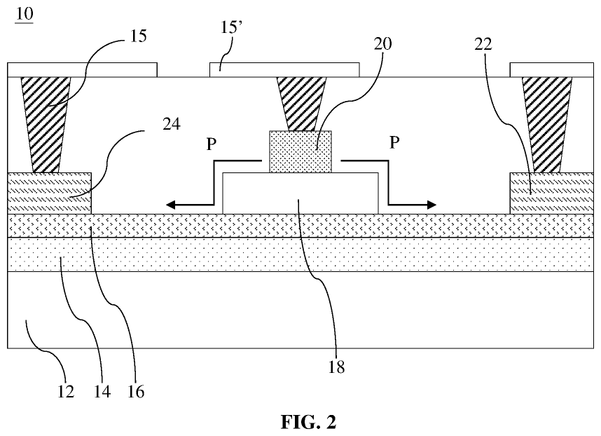

To clearly describe the effect of the semiconductor device 100A, FIG. 2 is a vertical cross-sectional view of a semiconductor device 10 according to a comparative embodiment. The semiconductor device 10 includes a substrate I2, nitride-based semiconductor layers I4 and 16, a doped III-V semiconductor layer 18, S/D electrodes 22 and 24, a plurality of contact vias 15 and a patterned electrode layer 15′. The doped III-V semiconductor layer 18 does not have the current-leakage barrier portions.

In the semiconductor device 10 of the comparative embodiment, since the profile of the doped III-V semiconductor layer 18 is defined by a dry-etching process, the sidewall or the surface thereof may be damaged and thus dangling bonds and defects are generated/produced. During the operation period of the semiconductor device 10, without a configuration of any leakage barrier portion, some carriers may be combined with dangling bonds or defects at the sidewall or the surface due to agate voltage applied to the gate electrode 20. The carriers may flow from the gate electrode 20 to the S/D electrodes 22 or 24 through the surface or the sidewall of the doped III-V semiconductor layer 18 which results in leakage current (or can be referred to as gate leakage). The leakage current paths P negatively affect and reliability of the gate electrode 20, thereby deteriorating the electrical characteristic of the semiconductor device 10.

Referring to FIGS. 1A and 1, in the semiconductor devices 100A, the current-leakage barrier portions 122 and 124 with higher resistivity extend downward from the top surfaces 120ts of the doped III-V semiconductor layer 120. Such configuration can block leakage current paths existing at the surface/sidewall of the doped III-V semiconductor layer 18 in FIG. 2, thereby reducing the chance of generating gate leakage current. That is, even if the sidewalls SW1 and SW2 have defects during the patterning process thereof, the higher resistivity of the current-leakage barrier portions 122 and 124 can reduce possible leakage current path.

Moreover, during the operation of the semiconductor device 100A, the electrical field at the edge of the doped III-V semiconductor layer 120 (i.e., a source side or a drain side) would be stronger than that of the other portions thereof. The configuration of the current-leakage barrier portions 122 and 124 can have the greater breakdown field strength than that of the remaining portion 126 of the doped III-V semiconductor layer. Therefore, the breakdown voltage can be enhanced, and thus the semiconductor device 100A can be applied to a higher voltage condition with good reliability and electrical characteristics.

In some embodiments, a ratio can be defined as L1(or L2)/T, where T is the thickness of an entirety of the doped III-V semiconductor layer 120, and the ratio is in a range from about 0.01 to about 1, which will give the semiconductor device 100A better performance.

The passivation layer 140 is disposed over the nitride-based semiconductor layer 106. The passivation layer 140 covers a top surface of the nitride-based semiconductor layer 106. The passivation layer 140 can at least cover the edges E1 and E2 of the gate electrode 130. The passivation layer 140 can be formed for a protection purpose or for enhancing the electrical properties of the device (e.g., by providing an electrically isolation effect between/among different layers/elements). The exemplary materials of the passivation layers 140 can include, for example but are not limited to, SiNₓ, SiOₓ, Si₃N₄, SiON, SiC, SiBN, SiCBN, oxides, nitrides, poly(2-ethyl-2-oxazoline) (PEOX), or combinations thereof. In some embodiments, the passivation layers 140 can be a multi-layered structure, such as a composite dielectric layer of Al₂O₃/SiN, Al₂O₃/SiO₂, AlN/SiN, AlN/SiO₂, or combinations thereof.

The contact vias 150 are disposed in the passivation layer 140. The contact vias 150 extend longitudinally so as to electrically connect the gate electrode 130 and the S/D electrodes 110 and 112. Top surfaces of the contact vias 150 can be free from the coverage of the passivation layer 140. The exemplary materials of the contact vias 150 can include, but are not limited to, conductive materials, for example, metal or alloys.

The patterned conductive layer 152 is disposed on the passivation layer 140 and the contact vias 150. The patterned conductive layer 152 is in contact with the contact vias 150. The patterned conductive layer 152 may have metal lines, pads, traces, or combinations thereof, such that the patterned conductive layer 152 can form at least one circuit. The patterned conductive layer 152 may include a single film or multilayered film having Ag, Al, Cu, Mo, Ni, Ti, alloys thereof, oxides thereof, nitrides thereof, or combinations thereof.

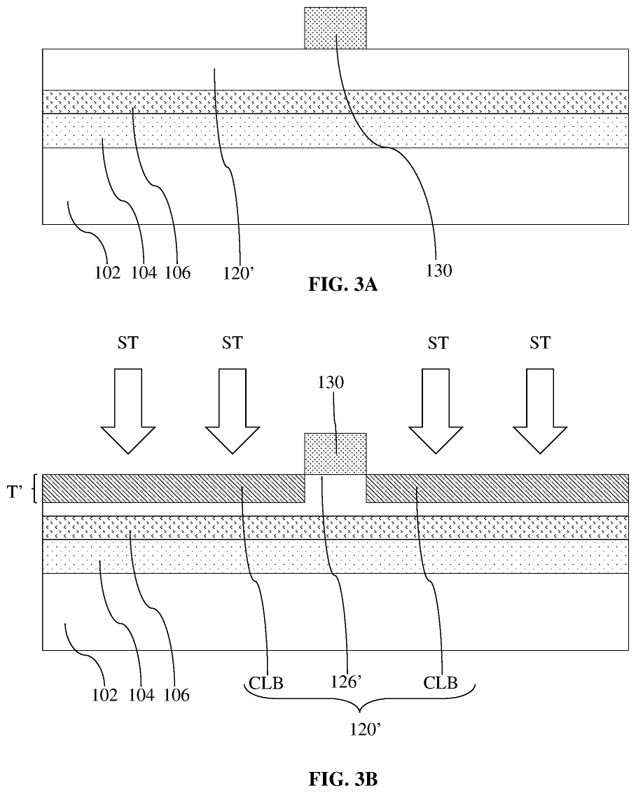

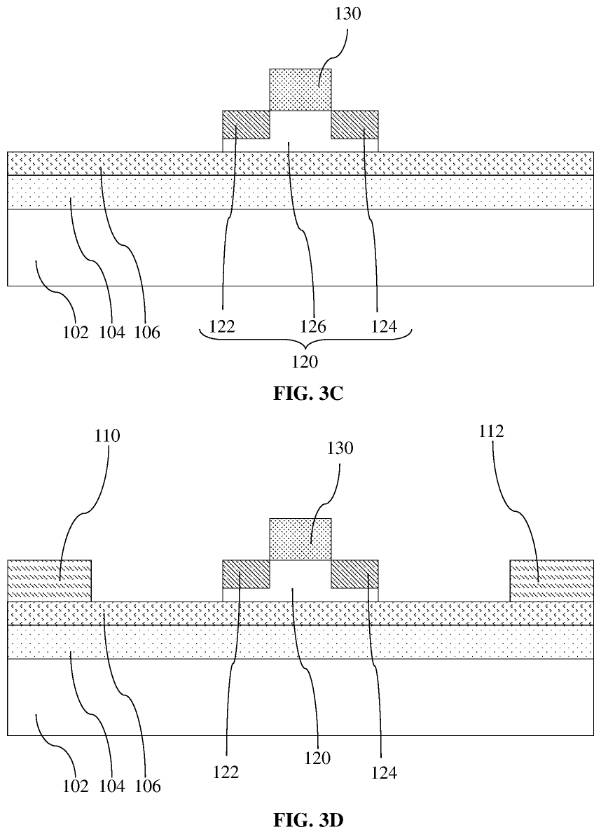

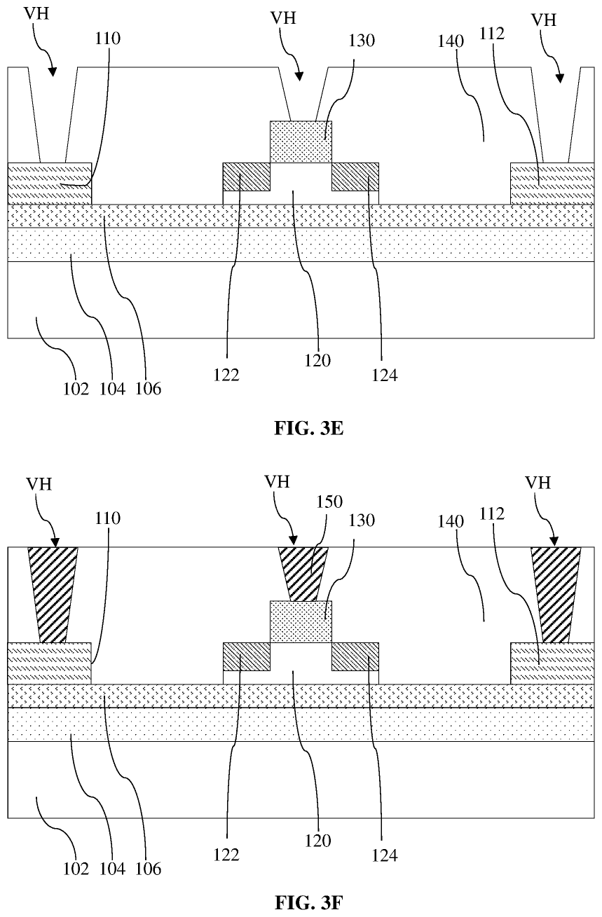

Different stages of a method for manufacturing the semiconductor device 100A are shown in FIG. 3A, FIG. 3B, FIG. 3C, FIG. 3D, FIG. 3E, and FIG. 3F, described below. In the following, deposition techniques can include, for example but are not limited to, atomic layer deposition (ALD), physical vapor deposition (PVD), chemical vapor deposition (CVD), metal organic CVD (MOCVD), plasma enhanced CVD (PECVD), low-pressure CVD (LPCVD), plasma-assisted vapor deposition, epitaxial growth, or other suitable processes.

Referring to FIG. 3A, a substrate 102 is provided. The nitride-based semiconductor layers 104, 106 and the blanket doped III-V semiconductor blanket layer 120′ can be formed over the substrate 102 in sequence by using deposition techniques. A gate electrode 130 can be formed above the blanket doped III-V semiconductor blanket layer 120′. The formation of the gate electrode 130 includes deposition techniques and a patterning process, wherein the deposition techniques can be performed for forming a blanket layer, and the patterning process can be performed for removing excess portions thereof. In some embodiments, the patterning process can include photolithography, exposure and development, etching, other suitable processes, or combinations thereof.

Referring to FIG. 3B, a surface treatment ST is performed on the blanket doped III-V semiconductor layer 120′ using the gate electrode 130 as a mask, such that at least one portion of the blanket doped III-V semiconductor layer 120′ becomes a current-leakage barrier portion CLB. The surface treatment ST can be terminated when the current-leakage barrier portion CLB spans a predetermined thickness T′ of the blanket doped III-V semiconductor layer 120′. In the exemplary illustration of FIG. 3B, the predetermined thickness T′ is less than the entire thickness of the blanket doped III-V semiconductor layer 120′.

In some embodiments, the surface treatment ST can include an oxidation process such as oxygen plasma treatment and rapid thermal annealing (RTA) process. Oxygen would react with the elements in the blanket doped III-V semiconductor layer 120′, and thus the gallium-oxide compound with high resistivity such as Ga₂O₃, GaON, GaMgON, or combinations thereof are formed therein. On the other hand, the dangling bonds or other defects at the surface of the blanket doped III-V semiconductor layer 120′ can be removed by the RTA process so as to achieve surface reconstruction. In some embodiments, the surface treatment ST can be achieved by performing a doping process, such as by ion implantation, with high resistive elements on the blanket doped III-V semiconductor layer 130. The high resistive elements can include, for example but are not limited to, fluorine (F), nitrogen (N), oxygen (O), argon (Ar), silicon (Si) or combinations thereof to the. Therefore, the resistivity of the current-leakage barrier portion CLB is higher than that of the rest portion 126′ of the blanket doped III-V semiconductor layer 120′. Further, the process of ion implantation may damage the crystal structure in regions 122 and 124, thereby increasing the resistivity.

Furthermore, during the surface treatment ST, the gate electrode 130 serves as a mask so as to define the distribution of the current-leakage barrier portion CLB and the rest portion 126′ of the blanket doped III-V semiconductor layer 120′. The width of the top surface of the remaining portion 126′ of the doped III-V semiconductor layer 120′ is defined by geometric characteristics of the gate electrode 130; specifically, by the width of the gate electrode 130. Using the gate electrode 130 to serve as the mask achieves self-aligned technique, which would be advantageous to omit extra process steps and avoid overlay issues accompanied therewith.

Referring to FIG. 3C, the blanket doped III-V semiconductor layer 120′ is patterned to form a doped III-V semiconductor layer 120 wider than the gate electrode 130. The patterning process can be performed by photolithography, exposure and development, etching, other suitable processes, or combinations thereof. The etching process may involve with removing some portions of the blanket doped III-V semiconductor layer 120′ and the current-leakage barrier portion CLB so as to define the current-leakage barrier portions 122 and 124 and the rest portion 126 of the doped III-V semiconductor layer 120.

Referring to FIG. 3D, two or more S/D electrodes 110 and 112 are formed. The S/D electrodes 110 and 112 are located on the nitride-based semiconductor layer 106 and at opposite sides of the gate electrode 130. To be more specific, the S/D electrodes 110 and 112 can be formed by depositing a conductive material and then patterning the conductive material using an etching process.

Referring to FIG. 3E, depositing a blanket passivation layer and etching the blanket passivation layer to form a plurality of via holes VH, and thus the passivation layer 140 is formed. To be more specific, wet etching processes or dry etching processes (e.g., reactive ion etching, or RIE) may be used in combination with a mask (e.g., a photomask) to remove material from the blanket passivation layer. Each via hole VH results from such material removal.

Referring to FIG. 3F, the conductive material is deposited and introduced into these via holes VH, and thus the conductive vias 150 are formed. The conductive vias 150 are in contact with the S/D electrodes 110, 112 and the gate electrode 130, respectively. In some embodiments, the formation of the conductive vias 150 includes depositing a blanket conductive layer within the via holes VH and on the passivation layer 140. Then, portions of the blanket conductive layer on the passivation layer 140 are removed. The remaining portions of the blanket conductive layer are the conductive vias 150. After the formation of the conductive vias 150, the patterned conductive layer can be formed in contact with the conductive vias 150, obtaining the configuration of the semiconductor device 100A as shown in FIGS. 1A and 1B.

FIG. 4 is a cross-sectional view of a semiconductor device 100B according to some embodiments of the present disclosure. In the exemplary illustration of FIG. 4, the current-leakage barrier portions 122b and 124b of the doped III-V semiconductor layer 120b span entirely sidewalls SW1 and SW2, respectively. The current-leakage barrier portion 122b and 124b can extend downward to reach the interface I3. The profile of the remaining portion 126b of the doped III-V semiconductor layer 120b is a quadrilateral profile.

In addition, the manufacturing method for manufacturing the semiconductor device 100B is similar to the manufacturing method for manufacturing the semiconductor device 100A. The depths of the current-leakage barrier portion 122b and 124b can be controlled by tuning at least one parameter, such as time, strength of the surface treatment, temperature, or pressure. For example, in the stage of FIG. 3B, performing the surface treatment ST can be terminated when the current-leakage barrier portion CLB spans an entire thickness of the blanket doped III-V semiconductor layer 120′.

FIG. 5 is a cross-sectional view of a semiconductor device 100C according to some embodiments of the present disclosure. In the exemplary illustration of FIG. 5, the remaining portion 126c of the doped III-V semiconductor layer 120c has curved boundaries. In response to the curved boundaries, the remaining portion 126c of the doped III-V semiconductor layer 120c has a profile changing from narrow to wide along a direction pointing outward from the gate electrode 130 toward the nitride-based semiconductor layer 106. In the other point of view, each of the current-leakage barrier portions 122c and 124c has curved profile.

FIG. 6 is a cross-sectional view of a semiconductor device 100D according to some embodiments of the present disclosure. In the exemplary illustration of FIG. 6, the current-leakage barrier portions 122d and 124d have curved boundaries and span entirely sidewalls SW1 and SW2, respectively. Furthermore, the remaining portion 126d of the doped III-V semiconductor layer 120d is separated from the sidewalls SW1 and SW2 of the doped III-V semiconductor layer 120d by the current-leakage barrier portions 122d and 124d having the curved boundaries.

In addition, the manufacturing method for the semiconductor device 100C or 100D is similar to the manufacturing method for the semiconductor device 100A, which can be controlled by tuning at least one parameter, such as time, strength of the surface treatment ST, temperature, or pressure. For example, the strength of the surface treatment can be varied as being gradually decreasing with time.

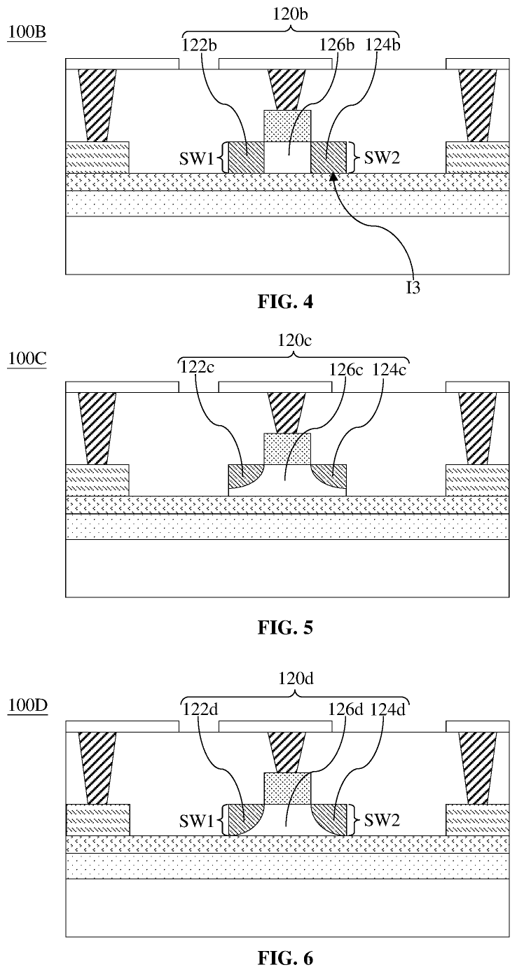

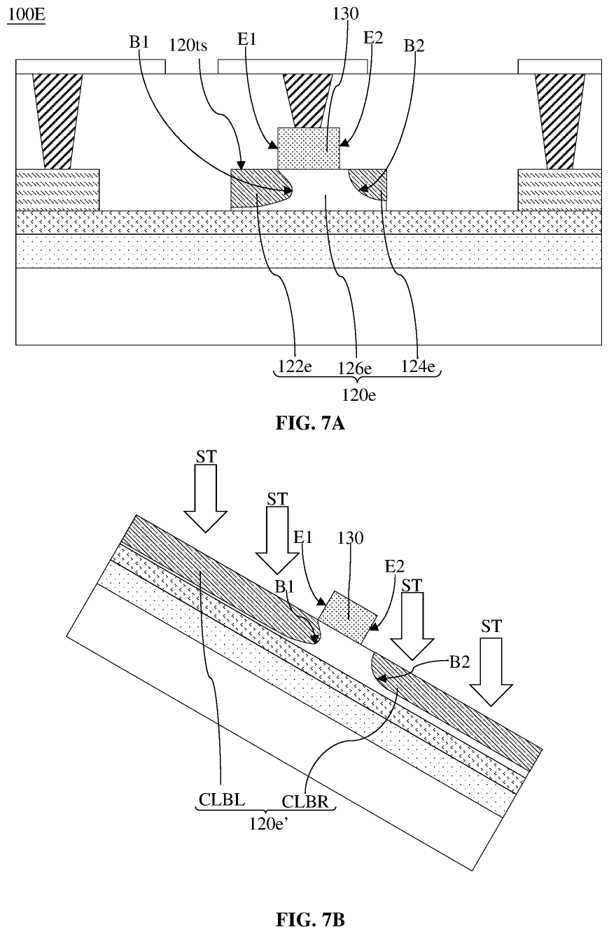

FIG. 7A is a cross-sectional view of a semiconductor device 100E according to some embodiments of the present disclosure. In the exemplary illustration of FIG. 7A, the current-leakage barrier portions 122e and 124e have profiles from a vertical cross-sectional view thereof that are asymmetrically-spaced about the gate electrode 130. Specifically, the current-leakage barrier portion 122e extend toward the current-leakage barrier portion 124e. As such, the current-leakage barrier portion 122e can have at least a portion located directly under with the gate electrode 130. That is, the portion of the current-leakage barrier portion 122e can overlap with the gate electrode 130. The current-leakage barrier portions 124e is free from vertically overlapping with the gate electrode 130. Furthermore, the inner boundary B1 of the current-leakage barrier portion 122e coincides with the edge E1 of the gate electrode 130 at the top surface 120ts of the doped III-V semiconductor layer 120e, and the inner boundary B2 of the current-leakage barrier portion 124e is spaced apart from the edge E2 of the gate electrode 130.

FIG. 7B shows a stage of a method for manufacturing the nitride-based semiconductor device 100E in FIG. 7A. The stage of FIG. 7B can replace the stage of FIG. 3B as afore-mentioned to manufacture the nitride-based semiconductor device 100E. The substrate 102 and the structure above can be tilted clockwise at an acute angle with respect to a vertical axis of the substrate 102 prior to performing the surface treatment ST, so that the left and right portions CLBL and CLBR of the blanket doped III-V semiconductor layer 120e′ are in different orientations. For example, the left portion CLBL of the blanket doped III-V semiconductor layer 120e′ is in a position higher than the right portion CLBR of the blanket doped III-V semiconductor layer 120e′. The inner boundary B1 of the left portion CLBL of the blanket doped III-V semiconductor layer 120e′ can be formed with coinciding the edge E1 of the gate electrode 130 since an interface therebetween (i.e., where the coincidence occurs) is free from the coverage of the gate electrode 130. The inner boundary B2 of the right portion CLBR of the blanket doped III-V semiconductor layer 120e′ can be formed with separated from the edge E2 of the gate electrode 130 since the gate electrode 130 can vertically block the surface treatment ST on the portion of the blanket doped III-V semiconductor layer 120e′.

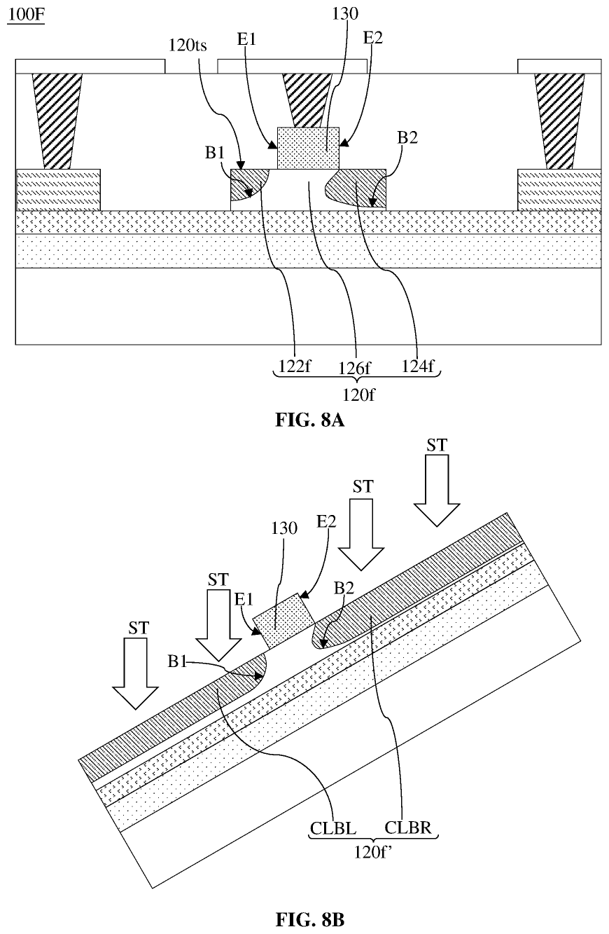

FIG. 8A is a cross-sectional view of a semiconductor device 100F according to some embodiments of the present disclosure. In the exemplary illustration of FIG. 8A, the current-leakage barrier portions 122f and 124f have profiles from a vertical cross-sectional view thereof that are asymmetrically-spaced about the gate electrode 130. Specifically, the current-leakage barrier portion 124f extend toward the current-leakage barrier portion 122f. As such, the current-leakage barrier portion 124f can have at least a portion located directly under with the gate electrode 130. That is, the portion of the current-leakage barrier portion 124f can overlap with the gate electrode 130. The current-leakage barrier portions 122e is free from vertically overlapping with the gate electrode 130. Furthermore, the inner boundary B2 of the current-leakage barrier portion 124f coincides with the edge E2 of the gate electrode 130 at the top surface 120ts of the doped III-V semiconductor layer 120f, and the inner boundary B1 of the current-leakage barrier portion 122f is spaced apart from the edge E1 of the gate electrode 130.

FIG. 8B shows a stage of a method for manufacturing the nitride-based semiconductor device in FIG. 8A. The stage of FIG. 8B can replace the stage of FIG. 3B as afore-mentioned to manufacture the nitride-based semiconductor device 100F. The substrate 102 and the structure above can be tilted counterclockwise at an acute angle with respect to a vertical axis of the substrate 102 prior to performing the surface treatment ST, so that left and right portions CLBL and CLBR of the blanket doped III-V semiconductor layer 120f are in different situations. For example, the right portion CLBR of the blanket doped III-V semiconductor layer 120f is in a position higher than the left portion CLBL of the blanket doped III-V semiconductor layer 120f. The inner boundary B2 of the right portion CLBR of the blanket doped III-V semiconductor layer 120f can be formed with coinciding the edge E2 of the gate electrode 130 since an interface therebetween (i.e., where the coincidence occurs) is free from the coverage of the gate electrode 130. The inner boundary B1 of the left portion CLBR of the blanket doped III-V semiconductor layer 120f can be formed with separated from the edge E1 of the gate electrode 130 since the gate electrode 130 can vertically block the surface treatment ST on the portion of the blanket doped III-V semiconductor layer 120f.

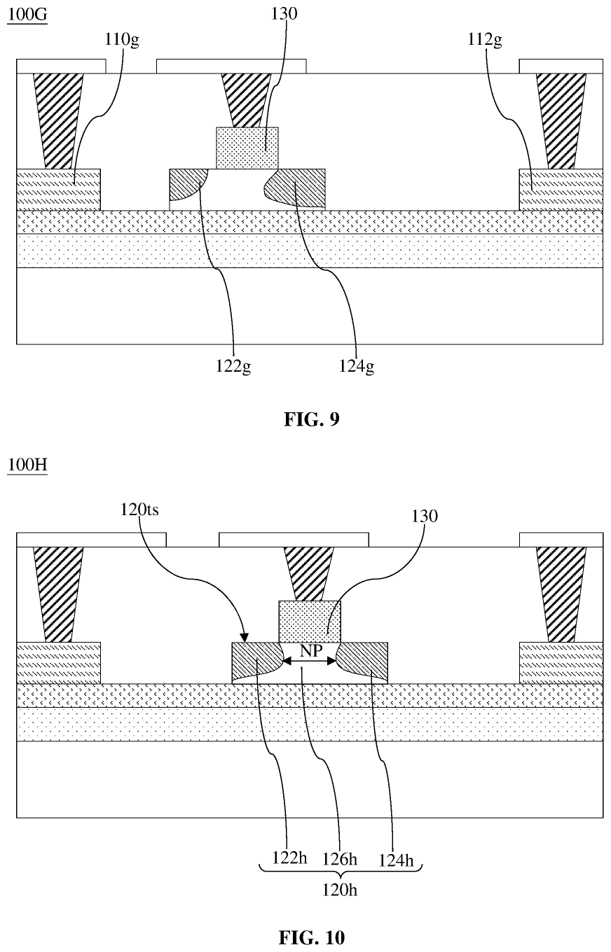

The profiles of the current-leakage barrier portions 122e and 124e asymmetrically-spaced about the gate electrode 130, as afore-mentioned, can be applied into a configuration that the S/D electrodes are asymmetrically-spaced about the gate electrode. For example, FIG. 9 is a cross-sectional view of a semiconductor device 100G according to some embodiments of the present disclosure. In the exemplary illustration of FIG. 9, the semiconductor device 100G includes S/D electrodes 110g and 112g asymmetrically-spaced about the gate electrode 130, similarly to the exemplary illustration of FIG. 8A. The S/D electrode 110g is closer to the gate electrode 130 than the S/D electrode 112G. Such arrangement might have the electrical field asymmetrical as well. Therefore, the asymmetrical profile of the current-leakage barrier portions 122g and 124g can adapt to the asymmetrical electrical field, making the semiconductor device 100G stable. In other embodiments, the configuration in the exemplary illustration of FIG. 7A also can be applied to a configuration that the S/D electrodes are asymmetrically-spaced about the gate electrode.

FIG. 9 is a cross-sectional view of a semiconductor device 100H according to some embodiments of the present disclosure. In the exemplary illustration of FIG. 9, the remaining portion 126h of the doped III-V semiconductor layer 120h has curved boundaries and the current-leakage barrier portions 122h and 124h extend toward each other. The current-leakage barrier portion 122h can have the inner boundary B1 coinciding with the edge E1 of the gate electrode 130 at the top surface 120ts of the doped III-V semiconductor layer 120h and extend to a position directly under the gate electrode 130. The current-leakage barrier portion 124h can have the inner boundary B2 coinciding with the edge E2 of the gate electrode 130 at the top surface 120ts of the doped III-V semiconductor layer 120h and extend to a position directly under the gate electrode 130. As such, the remaining portion 126h can change from wide to narrow and then from narrow to wide along a direction pointing outward from the gate electrode 130 toward nitride-based semiconductor layer 106. That is, the remaining portion 126h of the doped III-V semiconductor layer 120h can have a neck portion NP directly under the gate electrode 130.

To manufacture the nitride-based semiconductor 100G device in FIG. 9, the stages of FIG. 7B and FIG. 8B can be performed in sequence. For example, after the stage of FIG. 7B, the substrate 102 and the structure above are tilted counterclockwise, and then the surface treatment ST is performed again as shown in FIG. 8B, and vice versa.

It should be noted that the above semiconductor devices can be manufactured by the afore-mentioned different processes in order to meet different electrical requirements.

Based on above, in the embodiments of the semiconductor devices of the present disclosure, a pair of the current-leakage barrier portions with high resistivity are arranged in the doped III-V semiconductor layer and extend downward from a top surface of the doped III-V semiconductor layer. As such, the leakage current paths from the gate electrode toward the source electrode or the drain electrode are thus blocked. Since the current-leakage barrier portions are adjacent to the edges of the gate electrode, they can withstand a higher electric field near the edges of the gate electrode. Accordingly, semiconductor devices of the present disclosure can have low gate leakage current, high gate breakdown voltage, and have good reliability.

One additional point to make, the remaining portion of the doped III-V semiconductor layer defined by the current-leakage barrier portions has a width substantially the same as that of the interface between the gate electrode and the doped III-V semiconductor layer; hence, the self-aligning process can be applied to the manufacturing process of the semiconductor devices of the embodiments of the present disclosure which would be advantageous to reduce cost and improve alignment.

The embodiments were chosen and described in order to best explain the principles of the disclosure and its practical application, thereby enabling others skilled in the art to understand the disclosure for various embodiments and with various modifications that are suited to the particular use contemplated.

As used herein and not otherwise defined, the terms “substantially,” “substantial,” “approximately” and “about” are used to describe and account for small variations. When used in conjunction with an event or circumstance, the terms can encompass instances in which the event or circumstance occurs precisely as well as instances in which the event or circumstance occurs to a close approximation. For example, when used in conjunction with a numerical value, the terms can encompass a range of variation of less than or equal to 10% of that numerical value, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%. The term “substantially coplanar” can refer to two surfaces within micrometers of lying along a same plane, such as within 40 μm, within m, within 20 μm, within 10 μm, or within 1 μm of lying along the same plane.

As used herein, the singular terms “a,” “an,” and “the” may include plural referents unless the context clearly dictates otherwise. In the description of some embodiments, a component provided “on” or “over” another component can encompass cases where the former component is directly on (e.g., in physical contact with) the latter component, as well as cases where one or more intervening components are located between the former component and the latter component.

While the present disclosure has been described and illustrated with reference to specific embodiments thereof, these descriptions and illustrations are not limiting. It should be understood by those skilled in the art that various changes may be made and equivalents may be substituted without departing from the true spirit and scope of the present disclosure as defined by the appended claims. The illustrations may not necessarily be drawn to scale. There may be distinctions between the artistic renditions in the present disclosure and the actual apparatus due to manufacturing processes and tolerances. Further, it is understood that actual devices and layers may deviate from the rectangular layer depictions of the FIGS. and may include angles surfaces or edges, rounded corners, etc. due to manufacturing processes such as conformal deposition, etching, etc. There may be other embodiments of the present disclosure which are not specifically illustrated. The specification and the drawings are to be regarded as illustrative rather than restrictive. Modifications may be made to adapt a particular situation, material, composition of matter, method, or process to the objective, spirit and scope of the present disclosure. All such modifications are intended to be within the scope of the claims appended hereto. While the methods disclosed herein have been described with reference to particular operations performed in a particular order, it will be understood that these operations may be combined, sub-divided, or re-ordered to form an equivalent method without departing from the teachings of the present disclosure. Accordingly, unless specifically indicated herein, the order and grouping of the operations are not limitations.

1. A nitride-based semiconductor device, comprising:
a first nitride-based semiconductor layer;
a second nitride-based semiconductor layer disposed on the first nitride-based semiconductor layer and having a bandgap greater than a bandgap of the first nitride-based semiconductor layer;
a doped III-V semiconductor layer disposed over the second nitride-based semiconductor layer and having first and second current-leakage barrier portions which extends downward from a top surface of the doped III-V semiconductor layer;
a gate electrode disposed above the doped III-V semiconductor layer, wherein the gate electrode has a pair of opposite edges between the first and second current-leakage barrier portions, and one of the edges of the gate electrode coincides with the first current-leakage barrier portion;
a first source/drain (S/D) electrode disposed above the second nitride-based semiconductor layer, wherein the first current-leakage barrier portion is located between the first S/D electrode and the gate electrode; and
a second S/D electrode disposed above the second nitride-based semiconductor layer, wherein the second current-leakage barrier portion is located between the second S/D electrode and the gate electrode.

2. The semiconductor device of claim 1, wherein each of the first and second current-leakage barrier portions has a resistivity higher than that of a remaining portion of the doped III-V semiconductor layer, and the first and second current-leakage barrier portions define a profile of the remaining portion of the doped III-V semiconductor layer therebetween.

3. The semiconductor device of claim 2, wherein both the edges of the gate electrode coincide with the first and second current-leakage barrier portions, respectively, and the remaining portion of the doped III-V semiconductor layer has a top with a width the same as a width of the interface between the doped III-V semiconductor layer and the gate electrode.

4. The semiconductor device of claim 2, wherein each of the first and second current-leakage barrier portions has a curved profile from a vertical cross-sectional view thereof.

5. The semiconductor device of claim 4, wherein both the edges of the gate electrode coincide with the first and second current-leakage barrier portions, respectively, and the curved profiles of the first and second current-leakage barrier portions collectively make the profile of the remaining portion of the doped III-V semiconductor layer change from narrow to wide.

6. The semiconductor device of claim 5, wherein the profile of the rest portion of the doped III-V semiconductor layer changes from wide to narrow and then from narrow to wide such that the remaining portion of the doped III-V semiconductor layer has a neck portion.

7. The semiconductor device of claim 1, wherein the first and second current-leakage barrier portions have profiles from a vertical cross-sectional view thereof that are asymmetrically-spaced about the gate electrode.

8. The semiconductor device of claim 7, wherein the first and second S/D electrodes are asymmetrically-spaced about the gate electrode.

9. The semiconductor device of claim 7, wherein the first current-leakage barrier portion extends toward the second S/D electrode, such that the first current-leakage portion is located directly under the gate electrode.

10. The semiconductor device of claim 9, wherein the second current-leakage barrier portion is free from vertically overlapping with the gate electrode.

11. The semiconductor device of claim 7, wherein the second current-leakage barrier portion extends toward the first S/D electrode, such the second current-leakage portion is located directly under the gate electrode.

12. The semiconductor device of claim 1, wherein both the edges of the gate electrode coincide with the first and second current-leakage barrier portions, respectively, and the first and second current-leakage barrier portions extend toward each other to vertically overlap with the gate electrode.

13. The semiconductor device of claim 1, wherein at least one of the first and second current-leakage barrier portions extends downward to reach an interface between the doped III-V semiconductor layer and the second nitride-based semiconductor layer.

14. The semiconductor device of claim 13, wherein the first and second current-leakage barrier portions span entirely opposite sidewalls of the doped III-V semiconductor layer, respectively.

15. The semiconductor device of claim 1, wherein the doped III-V semiconductor layer is a p-doped gallium nitride (GaN) layer, and each of the first and second current-leakage barrier portions comprises Ga₂O₃, GaON, GaMgON, or combinations thereof.

16. A method for manufacturing a semiconductor device, comprising:
forming a first nitride-based semiconductor layer on a substrate;
forming a second nitride-based semiconductor layer on the first nitride-based semiconductor layer;
forming a blanket doped III-V semiconductor layer on the second nitride-based semiconductor layer;
forming a gate electrode on the blanket doped III-V semiconductor layer;
performing a surface treatment on the blanket doped III-V semiconductor layer using the gate electrode as a mask during the surface treatment, such that at least one portion of the blanket doped III-V semiconductor layer becomes a current-leakage barrier portion;
patterning the blanket doped III-V semiconductor layer to form a doped III-V semiconductor layer wider than the gate electrode; and
forming two or more source/drain (S/D) electrodes located on the second nitride-based semiconductor layer and located at opposite sides of the gate electrode.

17. The method of further comprising:
terminating the performing the surface treatment when the current-leakage barrier portion spans a whole thickness of the blanket doped III-V semiconductor layer.

18. The method of claim 16, further comprising:
tilting the substrate prior to the performing of the surface treatment.

19. The method of claim 16, wherein the surface treatment is performed by oxidizing the portion of the blanket doped III-V semiconductor layer.

20. The method of claim 16, wherein the surface treatment is performed by a doping process to the blanket doped III-V semiconductor layer.

21-25. (canceled)
